(19) United States
(12) Patent Application Publication
(10) Pub. No.: US 2026/0243977 A1
(43) Pub. Date: Aug. 20, 2026

(54) Optical Transmitter, Optical Transceiver Using the Same, and Optical Communication System

(71) Applicants: SUMITOMO OSAKA CEMENT CO., LTD., Tokyo (JP); WASEDA UNIVERSITY, Tokyo (JP)

(72) Inventors: Shingo TAKANO, Tokyo (JP); Yu KATAOKA, Tokyo (JP); Shotaro HIRATA, Tokyo (JP); Tomohiro KITA, Tokyo (JP)

(73) Assignees: SUMITOMO OSAKA CEMENT CO., LTD., Tokyo (JP); WASEDA UNIVERSITY, Tokyo (JP)

(21) Appl. No.: 19/473,097

(22) PCT Filed: Apr. 13, 2023
(86) PCT No.: PCT/JP2023/015040

§ 371 Date: Oct. 6, 2025

(51) Int. Cl. G02B 6/42

(52) U.S. Cl. CPC G02B 6/4239

(57) ABSTRACT

An object of the present invention is to provide an optical transmitter in which abnormal oscillation of a laser light source is suppressed and optical loss is small even in a case where an optical transmitter is configured by using a heterogeneous optical integrated circuit configured by connecting heterogeneous material substrates to each other.

The present invention provides an optical transmitter including a first substrate S1 that includes a first optical waveguide OW1 constituting an optical modulator unit, a second substrate S2 that is bonded to the first substrate S1 and includes a second optical waveguide OW2 for inputting a light wave to the first optical waveguide OW1, and a third substrate S3 that is bonded to the first substrate S1 and includes a third optical waveguide OW3 for outputting a light wave from the first optical waveguide OW1, in which the second optical waveguide OW2 constitutes a part of a laser light source, and a bonding interface between the first optical waveguide OW1 and the second optical waveguide OW2 is a resonance end surface of the laser light source.

### TECHNICAL FIELD

The present invention relates to an optical transmitter, an optical transceiver using the optical transmitter, and an optical communication system, and particularly to an optical transmitter using a heterogeneous optical integrated circuit.

### BACKGROUND

With the recent progress of informatization, a data capacity of information and communication has increased. In order to correspond to this, large-capacity transmission technology using wavelength multiplexing is being used. In this transmission technology, the number of light sources and the number of optical modulator units are large. Therefore, in a case where the installation volume of a data center, a base station, or the like is limited, it is essential to reduce the size of an optical device such as an optical transmitter.

In the related field, since heterogeneous material elements such as a light source and an optical modulator unit are optically connected by an optical fiber, a spatial optical system, or the like, the entire device is likely to be large. On the other hand, as disclosed in Patent Literature No. 1, a small optical transmitter has also been proposed in which respective elements are formed on different substrates and side surfaces of the substrates are bonded to each other. However, in a case where substrates having different refractive indices or optical waveguides are bonded to each other to form an optical system, an optical loss due to light reflection or light scattering at a bonding portion occurs.

In particular, in a case where a laser light source is incorporated into the optical transmitter, the light reflection at the bonding portion is input again as a return light to the light source, which causes abnormal oscillation.

### CITATION LIST

### Patent Literatures

Patent Literature No. 1: Japanese Laid-open Patent Publication No. 2017-3670
Patent Literature No. 2: Japanese Laid-open Patent Publication No. 2019-164260
Patent Literature No. 3: Japanese U.S. Pat. No. 5,093,527
Patent Literature No. 4: Japanese Laid-open Patent Publication No. 2015-154052

### SUMMARY OF INVENTION

### Technical Problem

An object of the present invention is to provide an optical transmitter that solves the above-described problem, and to provide an optical transmitter in which abnormal oscillation of a laser light source is suppressed and optical loss is small even in a case where an optical transmitter is configured by using a heterogeneous optical integrated circuit configured by connecting heterogeneous material substrates to each other.

In addition, an optical transceiver and an optical communication system using the optical transmitter are provided.

### Solution to Problem

In order to solve the above-described problems, an optical transmitter, an optical transceiver, and an optical communication system according to the present invention have the following technical features.

(1) An optical transmitter includes: a first substrate that includes a first optical waveguide constituting an optical modulator unit; a second substrate that is bonded to the first substrate and includes a second optical waveguide for inputting a light wave to the first optical waveguide; and a third substrate that is bonded to the first substrate and includes a third optical waveguide for outputting a light wave from the first optical waveguide, in which the second optical waveguide constitutes a part of a laser light source, and a bonding interface between the first optical waveguide and the second optical waveguide is a resonance end surface of the laser light source.

(2) The optical transmitter according to (1), in which a reflectivity of the bonding interface between the second optical waveguide and the first optical waveguide is adjusted to be higher than a reflectivity of a bonding interface between the first optical waveguide and the third optical waveguide.

(3) The optical transmitter according to (2), in which the reflectivity is adjusted by at least any one of disposing a multilayer film that increases the reflectivity at a bonding portion between the second optical waveguide and the first optical waveguide or disposing a multilayer film that decreases the reflectivity at a bonding portion between the first optical waveguide and the third optical waveguide.

(4) The optical transmitter according to (2), in which the reflectivity is adjusted by adjusting effective refractive indices of the optical waveguides connected to each other.

(5) The optical transmitter according to (2), in which the reflectivity is adjusted by adjusting an angle of each optical waveguide with respect to a normal line of a bonding surface of the optical waveguides connected to each other.

(6) The optical transmitter according to (1), in which a reflectivity of the bonding interface between the first optical waveguide and the second optical waveguide is in a range of 1% to 80%.

(7) The optical transmitter according to (1), in which the first optical waveguide has a folded structure, the second substrate and the third substrate are the same substrate, and an input port and output port of the first optical waveguide is formed on the same side surface of the first substrate.

(8) In the optical transmitter according to (1), the second substrate is configured with a substrate including an optical amplifier and a substrate including a wavelength filter.

(9) The optical transmitter according to (8), in which, in the substrate including the optical amplifier, an optical waveguide having a quantum well structure or a quantum dot structure is used.

(10) An optical transceiver including the optical transmitter according to any of (1) to (9).

(11) An optical communication system including the optical transceiver according to (10).

### Advantageous Effects of Invention

According to the present invention, the optical transmitter includes a first substrate that includes a first optical waveguide constituting an optical modulator unit; a second substrate that is bonded to the first substrate and includes a second optical waveguide for inputting a light wave to the first optical waveguide; and a third substrate that is bonded to the first substrate and includes a third optical waveguide for outputting a light wave from the first optical waveguide, in which the second optical waveguide constitutes a part of a laser light source, and a bonding interface between the first optical waveguide and the second optical waveguide is a resonance end surface of the laser light source. Therefore, by actively using the bonding interface of the optical waveguide as the resonance end surface, it is possible to suppress abnormal oscillation due to reflection at the bonding interface. Moreover, it is not necessary to separately prepare the resonance end surface that is essential for the laser light source.

In addition, since the reflectivity of the bonding interface between the second optical waveguide and the first optical waveguide is adjusted to be higher than the reflectivity of the bonding interface between the first optical waveguide and the third optical waveguide, the optical loss at the bonding interface can also be suppressed. Further, it is possible to provide an optical transceiver and an optical communication system using the optical transmitter that exhibits these excellent effects.

### BRIEF DESCRIPTION OF DRAWINGS

FIGS. 1A to 1C Diagrams representing examples of a combination of heterogeneous material substrates according to an optical transmitter.

FIGS. 2A to 2C Diagrams representing examples of a substrate including an optical modulator unit.

FIG. 3 A diagram representing an example of a substrate including an optical amplifier (SOA).

FIG. 4 A diagram representing an example of a substrate including a wavelength filter.

FIG. 5 A diagram representing reflection and transmission at a bonding interface of a substrate in the optical transmitter according to the present invention.

FIG. 6 A diagram representing a state of reflection on an end surface of the substrate.

FIG. 7 A diagram representing a state where an angle of an optical waveguide with respect to a bonding surface is adjusted.

FIGS. 8A and 8B Diagrams representing examples of a case where a spot size converter is provided at an end portion of the optical waveguide.

FIG. 9 A diagram representing a state in which a multilayer film is interposed at a bonding portion to adjust a reflectivity.

FIG. 10 A diagram representing a state where a reflectivity is adjusted by changing an effective refractive index of the optical waveguide.

FIGS. 11A and 11B Diagrams representing states where an effective refractive index of the optical waveguide including the spot size converter is adjusted.

FIG. 12 A diagram representing an example of a heterogeneous optical integrated circuit according to the optical transmitter of the present invention.

FIG. 13 A diagram representing another example of the heterogeneous optical integrated circuit according to the optical transmitter of the present invention.

### DESCRIPTION OF EMBODIMENTS

Hereinafter, the present invention will be described in detail using preferred examples.

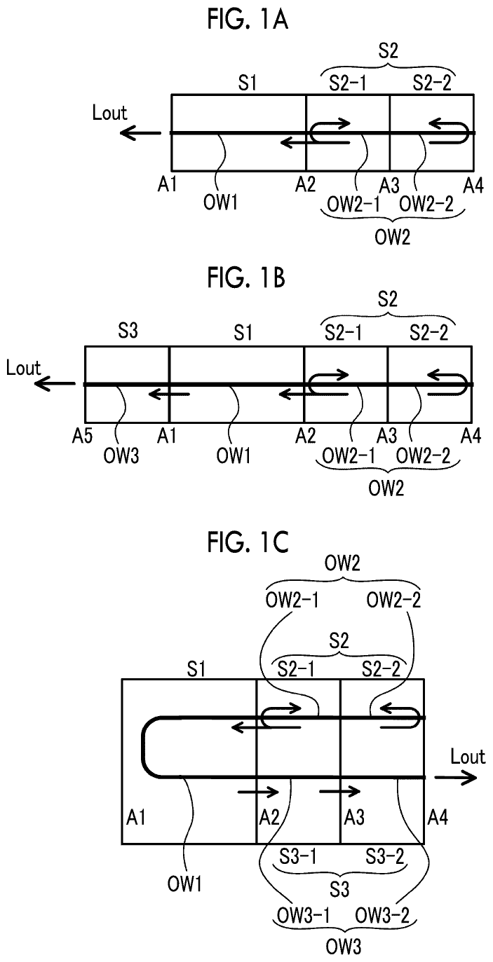

As shown in FIGS. 1A to 1C (particularly, FIG. 1B and FIG. 1C), the optical transmitter according to the present invention includes a first substrate S1 having a first optical waveguide OW1 that constitutes an optical modulator unit, a second substrate S2 bonded to the first substrate S1 and having a second optical waveguide OW2 that inputs a light wave to the first optical waveguide OW1, and a third substrate S3 bonded to the first substrate S1 and having a third optical waveguide OW3 that outputs a light wave from the first optical waveguide OW1, in which the second optical waveguide OW2 constitutes a part of the laser light source, and a bonding interface between the first optical waveguide OW1 and the second optical waveguide OW2 is a resonance end surface of the laser light source.

FIGS. 1A to 1C are diagrams representing examples of a configuration of an optical transmitter in which the optical devices formed on heterogeneous material substrates (S1 to S3) are integrated by bonding the respective substrates. In addition to forming the optical devices such as an optical modulator unit, an optical amplifier, and a wavelength filter on each substrate, an optical waveguide that guides light from the optical device to the outside of the substrate or guides light from the outside of the substrate to the optical device is also formed. Then, the side surfaces of the substrates (S1 to S3) are bonded to each other to connect the optical waveguide, thereby configuring an optical integrated circuit.

In FIG. 1A, the optical modulator unit is provided on the first substrate S1 to modulate a light wave passing through the optical waveguide OW1. In the drawing, the optical waveguide is shown by one straight line, but the line does not mean the shape of the optical waveguide, and indicates that the optical waveguide passing through the inside of the substrate is present.

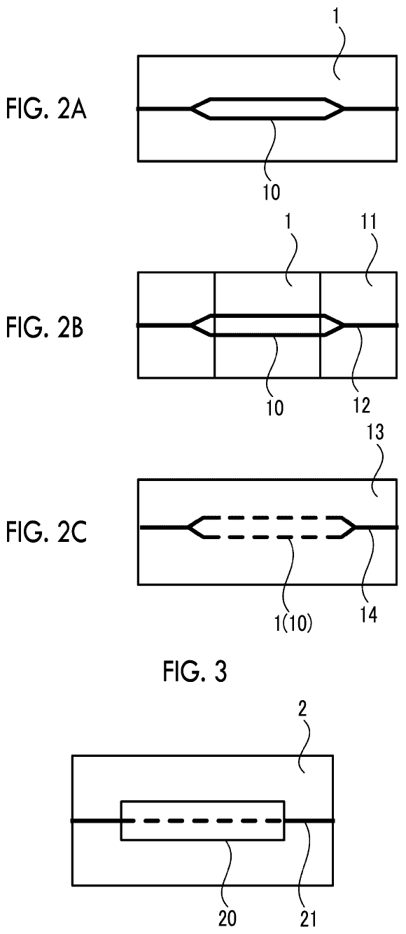

As an example of the substrate having the optical modulator unit, various forms can be selected as shown in FIGS. 2A to 2C. FIG. 2A shows a case where a rib-type optical waveguide 10 is formed on a dielectric thin plate 1 of a material having an electro-optic effect, for example, lithium niobate (LN), lithium tantalate (LT), barium titanate (BaTiO₃), PLZT (lead zirconate titanate lanthanum), or the like. In addition, an optical waveguide in which a high refractive index material such as Ti is thermally diffused in the dielectric thin plate 1 can also be used.

As disclosed in Patent Literature No. 2, FIG. 2B is a combination of a PLT (planar light circuit) in which a rib-type optical waveguide 12 is formed on a quartz-based thin plate 11 and a thin plate 1 such as LN in which a working unit of the optical modulator unit is formed. The LN thin plate 1 and the quartz-based thin plate 11 are configured by bonding substrate side surfaces to each other.

As disclosed in Patent Literature No. 3, FIG. 2B is a combination of the optical waveguide 1 (10) constituting the working unit of the optical modulator unit and other optical waveguides 14 such as a branching part are formed on a common substrate 13 using different materials.

The second substrate S2 constitutes a laser light source (the light wave is set to reciprocate between the substrate S2-1 and the substrate S2-2). In FIG. 1A, the laser light source is configured by a combination of two substrates, but the laser light source can also be realized as one substrate. In this case, it is necessary to form optical waveguides of different materials on one substrate as in Patent Literature No. 3. In addition, the second substrate used in the optical transmitter according to the present invention may mean the entire S2 or the substrate S2-1 adjacent to the first substrate S1.

In order to configure the laser light source, optical devices such as an optical amplifier that injects light into an optical waveguide, a reflecting surface (resonance end surface) for forming an optical path in which the light is reflected and reciprocates, and a wavelength filter that selects a specific wavelength from the reciprocating light are combined. For example, the optical amplifier or the wavelength filter may be incorporated into any of the substrate S2-1 or the substrate S2-2.

As a substrate including an optical amplifier (SOA), as shown in FIG. 3, an optical amplifier 20 is configured on the substrate, and an optical waveguide 21 connected to the optical amplifier 20 is disposed. As the optical amplifier, InGaAs, InGaAlAs, InP, InGaAsP, or the like, which is a compound semiconductor containing In, is suitable. InGaAsP is used as an active layer waveguide having a quantum well structure, and InAs is used as an active layer waveguide having a quantum dot structure. An electrode (not shown) is disposed in the optical amplifier 20 in FIG. 3.

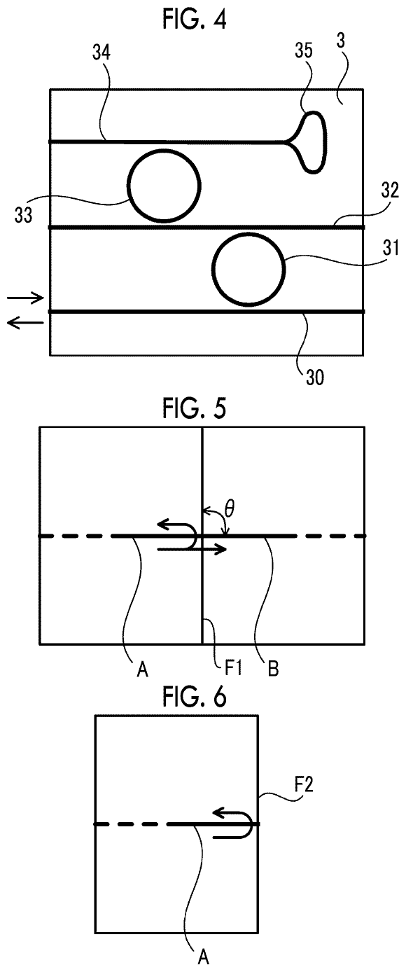

As the substrate including the wavelength filter, as shown in FIG. 4, silicon photonics (SiPh) in which Si is used in the core portion of the optical waveguide and SiO₂ is used in the clad portion can be used. As the core portion of the optical waveguide, Si, SiN, SiON, TiO₂, ZrO₂, and the like can be used. In addition, a quartz-based substrate such as a PLC can also be used.

The wavelength filter is composed of the optical waveguides 30, 32, and 34 which are linear waveguides, the ring waveguides 31 and 33, the folded waveguide 35, and the like.

As disclosed in Patent Literature No. 3, with respect to the light wave propagating in the optical waveguide 20, the light wave of the specific wavelength is coupled into the ring waveguide 31 by the ring waveguide 31, and is further released to the optical waveguide 32. In the light wave that propagates in the optical waveguide 32, the light wave of a specific wavelength is drawn into the ring waveguide 33 by the ring waveguide 33, and is further released to the optical waveguide 34. A loop-shaped folded waveguide 35 is provided at one end of the optical waveguide 34, and a light wave turns back in the folded waveguide 35 and returns. The return light is radiated from the optical waveguide in the substrate 3 to the outside of the substrate through the ring waveguide 33, the optical waveguide 32, the ring waveguide 30, and the optical waveguide 30 again.

As described above, the wavelength is selected by the ring waveguide, and the light having a specific wavelength is emitted from the substrate 3 including the wavelength filter. The ring waveguide 31 or 33 may be one, or the folded waveguide 35 can be replaced with a reflective member (mirror). In addition, a heater can be disposed in the ring waveguide, and the specific wavelength to be selected can be made variable to form a wavelength variable filter.

In the optical transmitter of FIG. 1A, laser light having a specific wavelength is accumulated while the light wave reciprocates between substrates S2-1 and S2-2 in the second substrate S2. A feature of the optical transmitter according to the present invention is that a bonding interface between the second substrate S2 (substrate S2-1) and the first substrate S1 functions as a resonance end surface of the laser light source. With such a configuration, it is not necessary to separately provide a reflective member as disclosed in Patent Literature No. 1.

In FIG. 1B, the light wave emitted from the optical waveguide OW1 of the first substrate S1 is input to the third substrate S3. The third substrate is not particularly limited in optical device or function, but for example, a substrate including an optical amplifier is used, whereby it is possible to increase the intensity of the light wave on which optical modulation is performed at the first substrate and to emit the light wave. In addition, the third substrate can also be configured to be released through the optical waveguide of another substrate, as in the case of the PLC.

FIG. 1C shows a structure in which the optical waveguide on the first substrate S1 is folded back, and the returned light passes through the second substrate S2 as the third substrate S3, such that light is released to the outside of the optical transmitter. In a case where an optical amplifier is used in any of the substrates S2-1 or S2-2 in the optical waveguide OW2, another optical amplifier can be disposed to the optical waveguide OW3 passing through the same substrate to perform the amplification effect.

Similarly, in the cases of FIGS. 1B and 1C, the bonding portion between the second optical waveguide and the first optical waveguide functions as a resonance end surface, and it is necessary to configure a connection surface of the reference numeral A2 to increase the reflectivity. However, in the case of the transmitted light in FIG. 1B, and the return light in FIG. 1C, it is necessary to reduce the reflectivity and reduce the optical loss at the bonding portion between the first optical waveguide OW1 and the third optical waveguide OW3. In addition, the arrow along the optical waveguide in each drawing indicates a propagation direction or a reflection direction of a light wave.

In the optical transmitter according to the present invention, it is preferable that the bonding surface of the heterogeneous material substrates (S1 to S3) is set to an optimum reflectivity for the optical waveguide passing through the bonding surface, and particularly, the reflectivity of the bonding portion used for the resonance end surface is 1% to 80% and preferably 2% to 10%, and more preferably 3% to 6%.

As a method of adjusting the reflectivity, as shown in FIG. 5, the amount of light reflected from the interface F1 can be adjusted by adjusting the angle θ of the optical waveguide A or B with respect to the interface F1 of the bonding portion between the optical waveguide A and the optical waveguide B. In addition, as shown in FIG. 6, the reflectivity can also be adjusted by adjusting the angle of the optical waveguide A with respect to the end surface F2 of the substrate. The reflecting surface as shown in FIG. 6 can also be used for the right side end surface of the substrate S2-2 in FIGS. 1A and 1B.

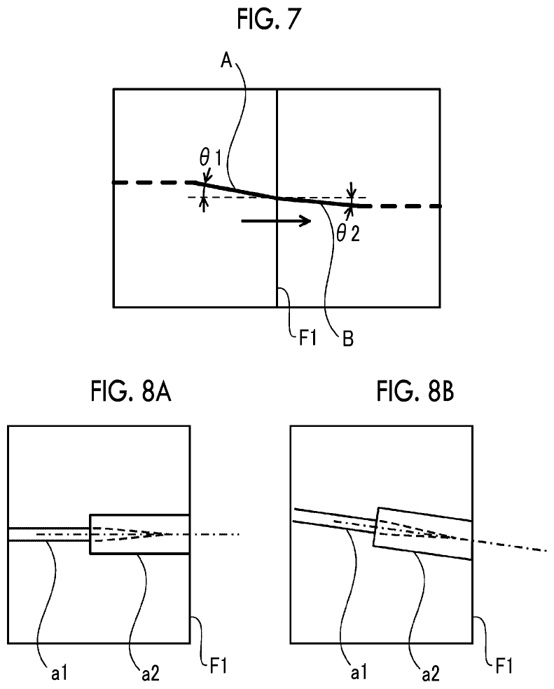

In addition, as shown in FIG. 7, in a case where the refractive indices of the substrates to be bonded are significantly different from each other, each of the input angles (θ1, θ2) of the optical waveguides with respect to the interface F1 can also be individually adjusted. Naturally, the condition for satisfying Snell's law is that the reflectivity is the lowest (the transmittance is the highest).

As shown in FIGS. 8A and 8B, even in a case where the spot size converter A2 is provided at the tip end of the optical waveguide A1, it is also possible to change the reflectivity by adjusting the angle with respect to the interface F1.

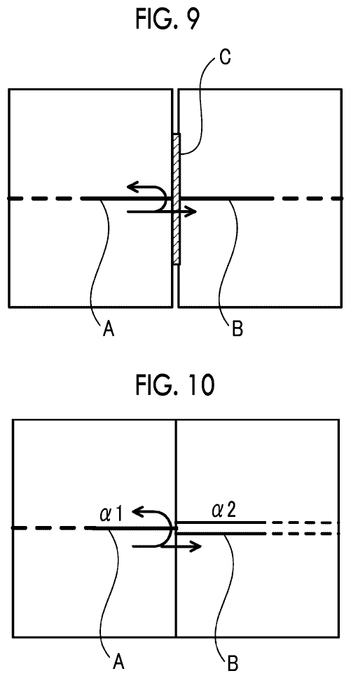

As shown in FIG. 9, it is also possible to dispose the multilayer film C at the interface of the bonding portion to adjust the reflectivity. Specifically, the multilayer film is designed and disposed such that the reflectivity is set to be high or low for light having a specific wavelength.

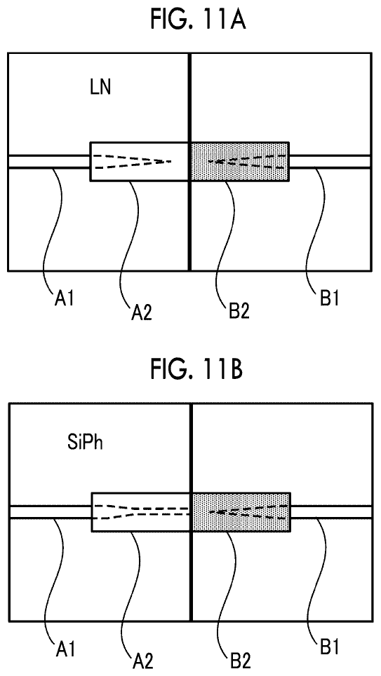

In FIG. 10, it is also possible to adjust the effective refractive indices (α1, α2) of the optical waveguides A and B to change the reflectivity. As a method of changing the effective refractive index, there is a method of changing the refractive index by changing a material constituting an optical waveguide, and there is a method of changing the effective refractive index by adjusting a cross section area of an optical waveguide. In addition, as shown in FIGS. 11A and 11B, the refractive index of the material constituting the spot size converter A2 or B2 can also be adjusted by, for example, a method such as using a material obtained by doping a resin material with a high refractive index material. In FIGS. 11A and 11B, in a case where the light wave travels from the left to the right and the optical waveguide Al is formed of LN, the optical waveguide Al is terminated in a tapered shape, as shown in FIG. 11A. On the other hand, in a case where the optical waveguide Al is formed of SiPh, the optical waveguide Al is connected to a fine optical waveguide after the tapered shape, and is set to have the same mode diameter even after the end surface is polished, as shown in FIG. 11B.

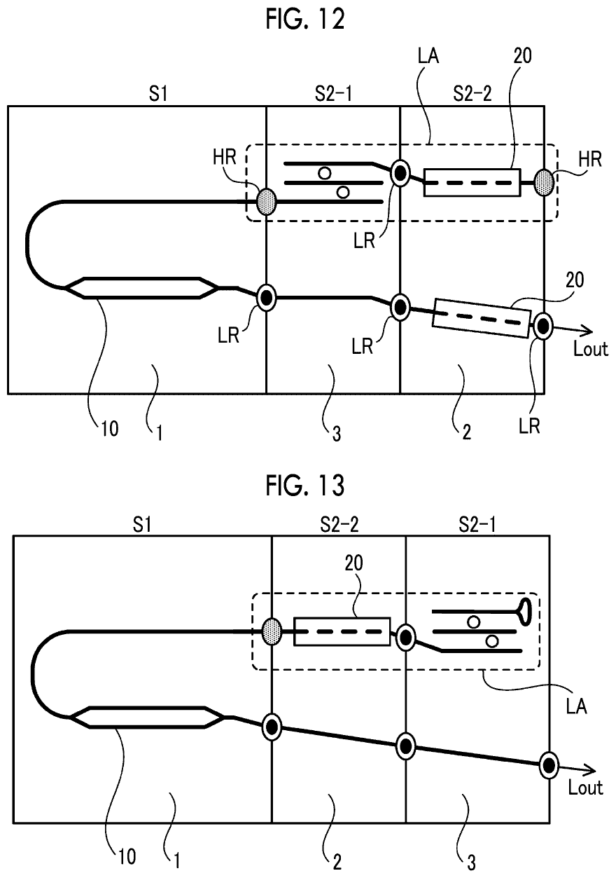

FIG. 12 shows a configuration in which a wavelength filter is disposed on a substrate S2-1 and an optical amplifier 20 is disposed on a substrate S2-2 as an example of the optical transmitter of FIG. 1C, and a laser light source LA is configured. In addition, FIG. 13 shows a laser light source LA in which the optical amplifier 20 is disposed on the substrate S2-1 and the wavelength filter is disposed on the substrate S2-2. In FIG. 12, in order to amplify the light passing through the first substrate S1, another optical amplifier is installed on the substrate S2-2.

At a portion of the substrate bonding portion denoted by a reference numeral HR in FIGS. 12 and 13, a high reflectivity needs to be set, and at a portion denoted by a reference numeral LR, a situation of a low reflectivity and a low optical loss needs to be accomplished.

The optical transmitter described above can be used as a part of an optical transceiver, and the optical transceiver incorporating the optical transmitter can also be used as a part of an optical communication system. As a result, it is possible to enjoy the advantages of the optical transmitter, that is, a smaller size, higher performance, and lower loss even in the optical transceiver or the optical communication system.

### INDUSTRIAL APPLICABILITY

As described above, according to the present invention, it is possible to provide an optical transmitter in which abnormal oscillation of a laser light source is suppressed and optical loss is small even in a case where an optical transmitter is configured by using a heterogeneous optical integrated circuit configured by connecting heterogeneous material substrates to each other. In addition, it is possible to provide an optical transceiver and an optical communication system using the optical transmitter.

### REFERENCE SIGNS LIST

S1 First substrate
S2 Second substrate
S3 Third substrate
OW1 First optical waveguide
OW2 Second optical waveguide
OW3 Third optical waveguide

1. An optical transmitter comprising:
a first substrate that includes a first optical waveguide constituting an optical modulator unit;
a second substrate that is bonded to the first substrate and includes a second optical waveguide for inputting a light wave to the first optical waveguide; and
a third substrate that is bonded to the first substrate and includes a third optical waveguide for outputting a light wave from the first optical waveguide, wherein
the second optical waveguide constitutes a part of a laser light source, and
a bonding interface between the first optical waveguide and the second optical waveguide is a resonance end surface of the laser light source.

2. The optical transmitter according to claim 1, wherein a reflectivity of the bonding interface between the second optical waveguide and the first optical waveguide is adjusted to be higher than a reflectivity of a bonding interface between the first optical waveguide and the third optical waveguide.

3. The optical transmitter according to claim 2, wherein the reflectivity is adjusted by at least any one of disposing a multilayer film that increases the reflectivity at a bonding portion between the second optical waveguide and the first optical waveguide or disposing a multilayer film that decreases the reflectivity at a bonding portion between the first optical waveguide and the third optical waveguide.

4. The optical transmitter according to claim 2, wherein the reflectivity is adjusted by adjusting effective refractive indices of the optical waveguides connected to each other.

5. The optical transmitter according to claim 2, wherein the reflectivity is adjusted by adjusting an angle of each optical waveguide with respect to a normal line of a bonding surface of the optical waveguides connected to each other.

6. The optical transmitter according to claim 1, wherein a reflectivity of the bonding interface between the first optical waveguide and the second optical waveguide is in a range of 1% to 80%.

7. The optical transmitter according to claim 1, wherein
the first optical waveguide has a folded structure,
the second substrate and the third substrate are the same substrate, and
an input port and output port of the first optical waveguide is formed on the same side surface of the first substrate.

8. The optical transmitter according to claim 1, wherein the second substrate is configured with a substrate including an optical amplifier and a substrate including a wavelength filter.

9. The optical transmitter according to claim 8, wherein, in the substrate including the optical amplifier, an optical waveguide having a quantum well structure or a quantum dot structure is used.

10. An optical transceiver comprising:
the optical transmitter according to claim 1.

11. An optical communication system comprising:
the optical transceiver according to claim 10.
